(19) United States
(12) Patent Application Publication
(10) Pub. No.: US 2025/0378791 A1
(43) Pub. Date: Dec. 11, 2025

(54) DISPLAY APPARATUS AND ELECTRONIC APPARATUS

(71) Applicant: Samsung Display Co., LTD., Yongin-si, Gyeonggi-do (KR)

(72) Inventors: Takyoung LEE, Yongin-si (KR); Hyuk KIM, Yongin-si (KR); Bogyeong KIM, Yongin-si (KR)

(21) Appl. No.: 19/225,167

(22) Filed: Jun. 2, 2025

(30) Foreign Application Priority Data
Jun. 7, 2024 (KR) 10-2024-0074577

(51) Int. Cl. G09G 3/3266

(52) U.S. Cl. CPC G09G 3/3266; G09G 2300/0819; G09G 2330/06

(57) ABSTRACT

A display apparatus includes an organic light-emitting diode, a scan driver including a first output terminal, a second output terminal, a first thin-film transistor electrically connected to the first output terminal, a second thin-film transistor electrically connected to the second output terminal, and a bootstrap capacitor electrically connected to a gate terminal of the second thin-film transistor, a driving thin-film transistor electrically connected to the organic light-emitting diode, a switching thin-film transistor electrically connected to a gate electrode of the driving thin-film transistor, and an initialization thin-film transistor electrically connected to the organic light-emitting diode and a source electrode of the driving thin-film transistor.

This application claims priority to Korean Patent Application No. 10-2024-0074577, filed on Jun. 7, 2024, and all the benefits accruing therefrom under 35 U.S.C. § 119, the content of which in its entirety is herein incorporated by reference.

### BACKGROUND

### 1. Field

Embodiments relate to a display apparatus and an electronic apparatus, and more particularly, to a display apparatus and an electronic apparatus capable of minimizing interference between signals.

### 2. Description of the Related Art

A display apparatus displays an image by receiving information about the image. Display apparatuses may be used as displays of small-sized products such as cellular phones, etc., or as displays of large-sized products such as a televisions, etc.

A display apparatus may include a plurality of pixels, which receive an electrical signal and then emit light, to display an image to the outside. Each pixel includes a light-emitting element. For example, an organic light-emitting display apparatus may include an organic light-emitting diode as the light-emitting element. Generally, an organic light-emitting display apparatus includes a thin-film transistor and an organic light-emitting diode formed on a substrate and operates with the organic light-emitting diode directly emitting light.

The display apparatus may also include a storage capacitor connected to a driving thin-film transistor and data may be written to the storage capacitor.

### SUMMARY

Embodiments include a display apparatus capable of minimizing interference between signals. However, this is merely one of features and the scope of the disclosure is not limited thereto.

Additional features will be set forth in part in the description which follows and, in part, will be apparent from the description, or may be learned by practice of the presented embodiments of the disclosure.

In an embodiment of the disclosure, a display apparatus includes an organic light-emitting diode, a scan driver including a first output terminal, a second output terminal, a first thin-film transistor, a second thin-film transistor, and a bootstrap capacitor, a driving thin-film transistor electrically connected to the organic light-emitting diode, a switching thin-film transistor electrically connected to a gate electrode of the driving thin-film transistor, and an initialization thin-film transistor electrically connected to the organic light-emitting diode and a source electrode of the driving thin-film transistor, wherein the first thin-film transistor is electrically connected to the first output terminal, the second thin-film transistor is electrically connected to the second output terminal, the bootstrap capacitor is electrically connected to a gate electrode of the first thin-film transistor and the first output terminal, the switching thin-film transistor includes a switching gate electrode electrically connected to the first output terminal, the initialization thin-film transistor includes an initialization gate electrode electrically connected to the second output terminal, and the gate electrode of the second thin-film transistor and the second output terminal are not electrically connected to each other.

In an embodiment, the first output terminal may output a first signal for turning on or off the switching thin-film transistor, and the second output terminal may output a second signal for turning on or off the initialization thin-film transistor.

In an embodiment, the scan driver may further include a node electrically connecting a gate electrode of the first thin-film transistor to a gate electrode of the second thin-film transistor.

In an embodiment, the node may be electrically connected to an electrode of the bootstrap capacitor.

In an embodiment, another electrode of the bootstrap capacitor may be electrically connected to a drain electrode of the second thin-film transistor and the second output terminal.

In an embodiment, the first signal may include a first rise section, a first maintain section after the first rise section, and a first fall section after the first maintain section, and the second signal may include a second rise section, a second maintain section after the second rise section, and a second fall section after the second maintain section.

In an embodiment, the first rise section and the second rise section may start simultaneously with each other.

In an embodiment, the first fall section may start during the second maintain section, and the first fall section may end before the second fall section starts.

In an embodiment, the scan driver may further include a node electrically connecting a gate electrode of the first thin-film transistor to a gate electrode of the second thin-film transistor, a third signal may be applied to the node, and the third signal may include a first high-level section, a second high-level section, and a third high-level section, wherein the second high-level section starts, after the first high-level section, simultaneously with the first rise section and has a voltage higher than the first high-level section, and the third high-level section starts, after the second high-level section, simultaneously with the first fall section and has a voltage lower than the second high-level section.

In an embodiment, the third high-level section may have a voltage higher than the first high-level section.

In an embodiment, the third high-level section may be maintained, after the first fall section ends, until the second fall section starts.

In an embodiment, the third signal may further include a fourth high-level section which starts, after the third high-level section, simultaneously with the second fall section and has a voltage lower than the third high-level section.

In an embodiment, the fourth high-level section may end after the second fall section ends.

In an embodiment, the first thin-film transistor may include a first semiconductor layer having a first area in a plan view, the second thin-film transistor may include a second semiconductor layer having a second area in the plan view, and the first area may be less than the second area.

In an embodiment, the first thin-film transistor may include a first semiconductor layer including a first active area, the second thin-film transistor may include a second semiconductor layer including a second active area, and a first width of the first active area may be less than a second width of the second active area.

In an embodiment of the disclosure, a display apparatus includes an organic light-emitting diode, a scan driver including a first output terminal, a second output terminal, a first thin-film transistor, a second thin-film transistor, and a first bootstrap capacitor, a driving thin-film transistor electrically connected to the organic light-emitting diode, a switching thin-film transistor electrically connected to a gate electrode of the driving thin-film transistor, and an initialization thin-film transistor electrically connected to the organic light-emitting diode and a source electrode of the driving thin-film transistor, wherein the first thin-film transistor is electrically connected to the first output terminal, the second thin-film transistor is electrically connected to the second output terminal, the first bootstrap capacitor is electrically connected to a gate electrode of the first thin-film transistor and the first output terminal, the switching thin-film transistor includes a switching gate electrode electrically connected to the first output terminal, the initialization thin-film transistor includes an initialization gate electrode electrically connected to the second output terminal, and a second bootstrap capacitor electrically connected between a gate electrode of the second thin-film transistor and the second output terminal is not included.

In an embodiment, a capacity of the first bootstrap capacitor may be greater than a capacity of the second bootstrap capacitor.

In an embodiment, the capacity of the first bootstrap capacitor may be twice the capacity of the second bootstrap capacitor.

In an embodiment, the first thin-film transistor may include a first semiconductor layer having a first area in a plan view, the second thin-film transistor may include a second semiconductor layer having a second area in the plan view, and the second area may be less than the first area.

In an embodiment of the disclosure, an electronic apparatus includes a memory which stores data information, a processor which generates data signals and/or control signals based on the data information and a display apparatus which operates based on the data signals and/or the control signals. The display apparatus includes an organic light-emitting diode, a scan driver including a first output terminal, a second output terminal, a first thin-film transistor, a second thin-film transistor, and a bootstrap capacitor, a driving thin-film transistor electrically connected to the organic light-emitting diode, a switching thin-film transistor electrically connected to a gate electrode of the driving thin-film transistor, and an initialization thin-film transistor electrically connected to the organic light-emitting diode and a source electrode of the driving thin-film transistor, wherein the first thin-film transistor is electrically connected to the first output terminal, the second thin-film transistor is electrically connected to the second output terminal, the bootstrap capacitor is electrically connected to a gate electrode of the first thin-film transistor and the first output terminal, the switching thin-film transistor includes a switching gate electrode electrically connected to the first output terminal, the initialization thin-film transistor includes an initialization gate electrode electrically connected to the second output terminal, and the gate electrode of the second thin-film transistor and the second output terminal are not electrically connected to each other.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic block diagram of an embodiment of a pixel and a display apparatus including the pixel;

FIG. 2 is a schematic plan view of an embodiment of a pixel and a display apparatus including the pixel;

FIG. 3 is a schematic equivalent circuit diagram of the pixel of the display apparatus of FIG. 1;

FIG. 4 is a schematic cross-sectional view of a portion of the display apparatus of FIG. 1;

FIG. 5 is a schematic circuit diagram of a portion of a scan driver electrically connected to a pixel circuit of FIG. 3;

FIG. 6 is a schematic graph of signals respectively applied to a node, a first output terminal, and a second output terminal of FIG. 5;

FIG. 7 is a circuit diagram showing an embodiment of the whole circuit diagram including a portion of the scan driver of FIG. 5;

FIG. 8 is a schematic circuit diagram of a portion of a scan driver electrically connected to a pixel circuit of a display apparatus according to a comparative embodiment; and

FIG. 9 is a schematic graph of signals respectively applied to a node, a first′ output terminal, and a second′ output terminal of FIG. 8.

FIG. 10 is a block diagram of an electronic device; and

FIG. 11 shows schematic views of various electronic devices.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in detail. The effects and characteristics of the disclosure and methods of achieving the same will become apparent by referring to the embodiments described below in detail with reference to the drawings. However, the disclosure is not limited to the embodiments disclosed hereinafter and may be realized in various forms.

Hereinafter, embodiments will be described in detail by referring to the accompanying drawings, wherein, when describing the accompanying drawings, elements that are the same as or corresponding to each other will be assigned the same reference numerals, repeated descriptions thereof will not be given.

In embodiments to be described hereinafter, when elements, such as a layer, a film, an area, a plate, etc. are referred to as being “on” another element, the reference may indicate not only a case where the element is “directly on” the other element, but also a case where yet another element is between the element and the other element. Also, in embodiments to be described hereinafter, when elements, such as a layer, a film, an area, a plate, etc. are referred to as being “below” another element, the reference may indicate not only a case where the element is “directly below” the other element, but also a case where yet another element is between the element and the other element.

Also, for convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings. That is, for convenience of explanation, the sizes, thicknesses, and ratios of the elements illustrated in the drawings may be exaggerated and/or simplified for clarity. Accordingly, spatially relative terms, such as “below,” “under,” “lower,” “bottom,” “on,” “above,” etc., may be used, in this specification, to easily describe the relationship between elements or features.

While the terms used in this specification to describe a space, a direction, etc. are meant to describe the space, the direction, etc. illustrated in the drawings, the terms may be understood to describe various other directions or perspectives. For example, when an apparatus or an element illustrated in the drawings is turned over, the apparatus or the element described as “below” may be interpreted as a different direction (for example, as being rotated by 90 degrees, as being in the opposite direction, or the like). For example, when an apparatus or an element illustrated in the drawings is turned over, the apparatus or the element described as “above” may be interpreted as a different direction (for example, as being rotated by 90 degrees, as being in the opposite direction, or the like). Thus, “below” and “above” may include both an upper direction and a lower direction. Also, an apparatus or an element may be arranged in a different direction from the drawings, and the description with respect to the space or the direction in the specification may be variously interpreted.

In this specification, an order of a process or an order of a method understood from the description about a processing process and a manufacturing method may be different from the order of the description. For example, sequentially described two processes or two methods may be simultaneously or substantially simultaneously performed or may be performed in the order opposite to a described order.

In the embodiments hereinafter, the x-axis direction, the y-axis direction and the z-axis direction are not limited to the direction of three axes of the rectangular coordinate system, and may be interpreted in a broader sense. For example, the x-axis direction, the y-axis direction, and the z-axis direction may be perpendicular to one another, or may represent different directions that are not perpendicular to one another.

In this specification, the terms “first,” “second,” “third,” etc. may be used to describe a certain element in this specification, and the terms “first,” “second,” “third,” etc. may be used to identify one element from other elements.

When an element is referred to as being “connected to” or “coupled to” another element, the element may be understood to be directly or indirectly connected to or coupled to the other element.

Likewise, when an element is referred to as being “electrically connected to” another element, the element and the other element may be directly and electrically connected to each other or may be indirectly and electrically connected to each other through a conductive element.

Also, when it is described that an element is “between” two elements, the one element may be understood as the only element arranged between the two elements, or it may be understood that another element in addition to the one element may be arranged between the two elements.

Terms used in the specification are meant to describe an illustrative embodiment and are not intended for limitation of the disclosure. The singular expressions “a” and “an” used in the specification are intended to include a plural meaning unless apparently shown otherwise based on context.

For example, while expressions, such as “mixing,” “mixture,” “mix,” “have,” etc., explicitly describe the existence of a described feature, integer, operation, calculation, element, and/or component, the expressions do not exclude the existence or addition of one or more other features, integers, operations, calculations, elements, components, and/or groups.

For example, the term “and/or” includes a combination of arbitrary one or more or all of relevant listed items. For example, the expression “A and/or B” indicates A, B, or A and B. An expression, such as “at least one of,” may be used to refer to one or more elements from among a plurality of elements. For example, the expression “at least one of a, b, and c” or “at least one selected from the group consisting of a, b, and c” may indicate “a,” “b,” “c,” “a and b,” “b and c,” “a and c,” or “a, b, and c.”

For example, the terms “substantially” and “approximately” and the terms similar thereto may be used as approximative terms rather than terms indicating degrees and may be meant to describe intrinsic fluctuation of a measurement or calculation value recognizable by one of ordinary skill in the art. For example, to use the term “may” “may be,” or the like may be to indicate “one or more embodiments described in the specification.”

For example, that a layer has “the same layer structure” as another layer may denote that a plurality of layers included in the layer may be included in the other layer by the same order. For example, a plurality of layers included in a layer may include the same material and may be formed by the same order as a plurality of layers included in another layer.

Electronic or electrical devices and/or other arbitrary connected devices or components (e.g., some of various modules) in embodiments described in this specification may be realized by arbitrary appropriate hardware, firmware (e.g., an application-specific integrated circuit), or a combination of software, firmware, and hardware. In an embodiment, various components of these devices may be formed on one integrated circuit (“IC”) chip or separate IC chips, for example. Also, various components of these devices may be formed on a flexible printed circuit film, a tape carrier package (“TCP”), a printed circuit board (“PCB”), or a substrate. Also, various components of these devices may be a process or a thread, may be executed by one or more processors, may execute computer program instructions on one or more computing devices, and may interact with other system components which perform various functions described in the specification.

The computer program instructions may be, e.g., stored in a memory which may be realized on a computing device by a standard memory device such as random-access memory (“RAM”). Also, the computer program instructions may be, e.g., stored in other non-transitory computer-readable medium such as compact disc (“CD”)-read-only memory (“ROM”), a flash drive, etc. Also, it may be understood by one of ordinary skill in the art that functions of various computing devices may be integrated or combined in a single computing device or functions of a predetermined computing device may be distributed across one or more different computing devices without deviating from the concept and the range of embodiments.

Hereinafter, based on the descriptions above, a display apparatus in an embodiment will be described in detail below.

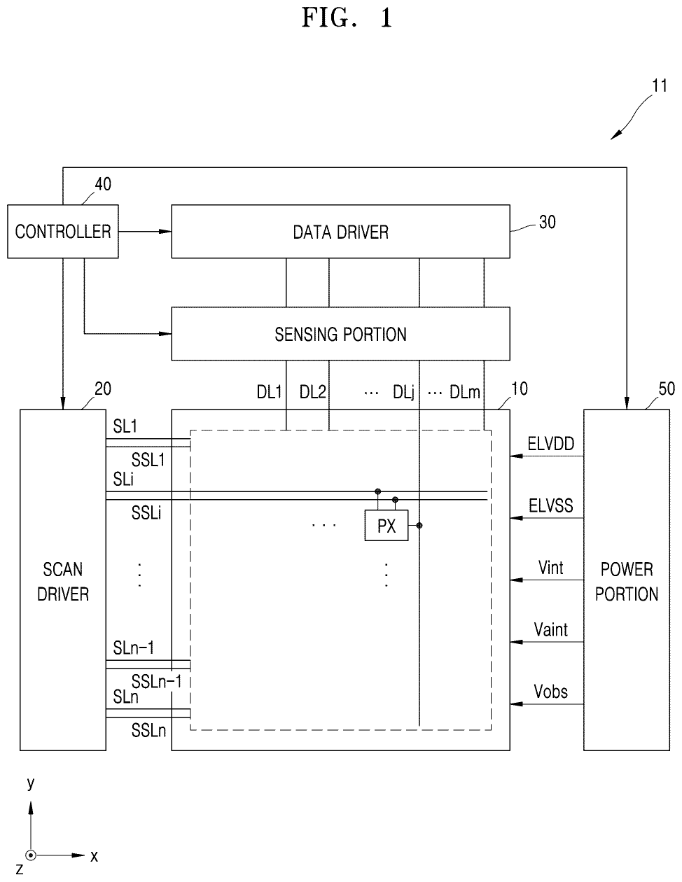

FIG. 1 is a schematic block diagram of an embodiment of a pixel PX and a display apparatus 11 including the pixel PX.

As illustrated in FIG. 1, the display apparatus 11 may include a display 10 (e.g., a display panel, etc.), a scan driver 20 (e.g., a gate driving circuit, etc.), a data driver 30 (e.g., a data driving circuit, etc.), a controller 40 (e.g., a timing controller, etc.), and a power portion 50 (e.g., a power supply, etc.). The scan driver 20, the data driver 30, the controller 40, and the power portion 50 may each be formed on a separate semiconductor chip or may be integrated on one semiconductor chip. Also, the scan driver 20 and/or the data driver 30 may be formed on the same substrate as the display 10. The display apparatus 11 may be a component for displaying an image, the component being included in an electronic device, such as a smartphone, a tablet personal computer, a notebook computer, a monitor, a television (“TV”), etc.

In the display 10, the pixel PX may be disposed in a plural number connected to a plurality of control lines (e.g., SL1 to SLn) extending in a first direction (e.g., an x-axis direction) and a plurality of data lines (e.g., DL1 to DLm) extending in a second direction (e.g., a y-axis direction). Here, n and m are natural numbers, respectively. For example, a z-axis direction may be perpendicular (substantially perpendicular) to a plane defined by the x-axis direction and the y-axis direction The plurality of pixels PX of the display 10 may be connected to a plurality of sensing scan lines (e.g., SSL1 to SSLn) extending in the first direction.

FIG. 1 illustrates the control lines (e.g., SL1 to SLn) as one signal line, for convenience. However, each of the control lines (e.g., SL1 to SLn) may include a plurality of signal lines. In an embodiment, a first control line SL1 may include three lines which respectively apply a scan signal, an initialization control signal, and an emission control signal, for example.

A unit pixel may include a plurality of sub-pixels for displaying a plurality of colors, respectively, to display various colors. In this specification, the pixel PX mainly denotes one sub-pixel. That is, in this specification, one pixel PX may be interpreted as being one sub-pixel.

The scan driver 20 may provide a plurality of scan signals to the pixels PX through the control lines (e.g., SL1 to SLn) and provide a sensing scan signal to the pixels PX through the sensing scan lines (e.g., SSL1 to SSLn). The data driver 30 may provide a data signal to the pixels PX through the data lines (e.g., DL1 to DLm).

The controller 40 may control the scan driver 20, the data driver 30, and the power portion 50. The controller 40 may output control signals (e.g., a scan signal, an initialization control signal, a sensing scan signal, an emission control signal, etc.) for controlling the scan driver 20, the data driver 30, and/or the power portion 50 and image data to the scan driver 20, the data driver 30, and/or the power portion 50, based on a horizontal synchronization signal and a vertical synchronization signal. The power portion 50 may apply a driving voltage ELVDD, a common voltage ELVSS, a first initialization voltage Vint, a second initialization voltage Vaint, and a bias voltage Vobs to the pixels PX.

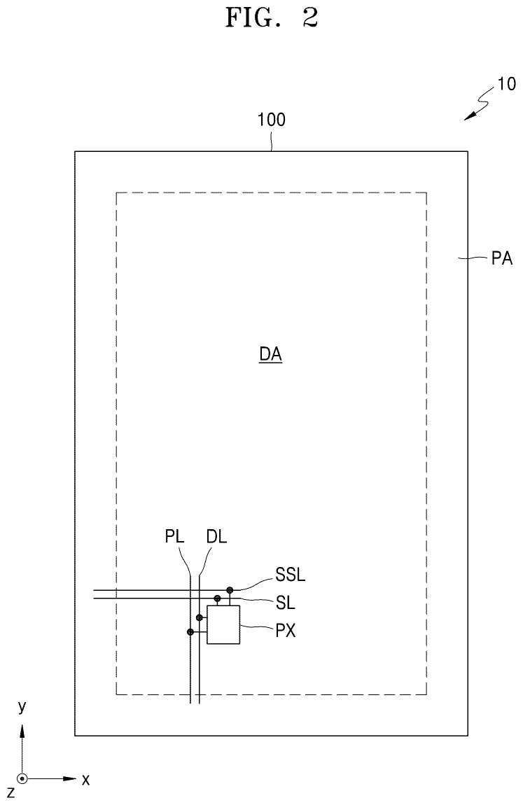

The pixel PX may include an organic light-emitting diode and a pixel circuit detachably connected to the organic light-emitting diode. The organic light-emitting diode may emit light of a brightness corresponding to a data signal. The pixel circuit may be electrically connected to the scan driver 20 to be described below. In an embodiment, the pixel circuit may be disposed in a display area DA (refer to FIG. 2), and the scan driver 20 may be disposed in a peripheral area PA (refer to FIG. 2), for example.

FIG. 2 is a schematic plan view of an embodiment of the pixel PX and the display apparatus 11 including the pixel PX.

As illustrated in FIG. 2, the display apparatus 11 in an embodiment may include the display 10. The display apparatus 11 may include every type of display apparatus that includes the display 10. In an embodiment, the display apparatus 11 may include various apparatuses, such as a smartphone, a tablet computer, a laptop, a television (“TV”), an advertising board, etc., for example. The display apparatus 11 in an embodiment may include thin-film transistors, a capacitor, etc., wherein the thin-film transistors, the capacitor, etc. may be realized by conductive layers and insulating layers.

The display 10 may include the display area DA and the peripheral area PA outside the display area DA. FIG. 2 illustrates that the display area DA has a quadrangular shape, e.g., rectangular shape. However, the disclosure is not limited thereto. The display area DA may have various shapes, such as a circular shape, an oval shape, a polygonal shape, a shape of a predetermined figure, etc.

The display area DA may be where an image is displayed, and a plurality of pixels PX may be arranged in the display area DA. Each pixel PX may include a display device, such as an organic light-emitting diode. Each pixel PX may emit red, green, or blue light, for example. The pixel PX may be connected to a pixel circuit including a thin-film transistor, a storage capacitor, etc.

The pixel PX may be connected to a control line SL which transmits a scan signal, a sensing scan line SSL which transmits a sensing scan signal (or an initialization control signal), a data line DL which crosses the control line SL and the sensing scan line SSL and transmits a data signal, a driving voltage line PL which supplies a driving voltage, etc. The data line DL and the driving voltage line PL may extend in a y-axis direction (hereinafter, a second direction) and the control line SL and the sensing scan line SSL may extend in an x-axis direction (hereinafter, a first direction).

The pixel PX may emit light having a brightness corresponding to an electrical signal from the pixel circuit electrically connected to the pixel PX. The display area DA may display a predetermined image through the light emitted from the pixel PX. For reference, the pixel PX may be a sub-pixel, wherein the sub-pixel may be defined as an emission area emitting light of any one color of red, green, and blue.

The peripheral area PA is where the pixel PX is not disposed and may be where an image is not displayed. In the peripheral area PA, the driving voltage line PL which drives the pixel PX, etc., may be disposed. Also, pads may be in the peripheral area PA, and a printed circuit board (“PCB”) including the controller 40 or an IC device such as a driver IC may be electrically connected to the pads in the peripheral area PA.

For reference, the display 10 may include a substrate 100, and thus, it may be described that the substrate 100 may include the display area DA and the peripheral area PA. Detailed features with respect to the substrate 100 will be described below.

Also, a plurality of transistors may be arranged in the display area DA. With respect to the plurality of transistors, according to a type (an N type or a P type) and/or an operation condition of the transistor, a first terminal of the transistor may be a source electrode or a drain electrode, and a second terminal of the transistor may be a different electrode from the first terminal. In an embodiment, when the first terminal is the source electrode, the second terminal may be the drain electrode, for example.

In an embodiment, the plurality of transistors may include a driving thin-film transistor, a switching thin-film transistor, an initialization thin-film transistor, an emission control thin-film transistor, etc., for example. The driving thin-film transistor may be connected between the driving voltage line PL and the organic light-emitting diode. In some cases, a compensation thin-film transistor may further be included.

The switching thin-film transistor may be connected to the data line DL and the driving thin-film transistor and may perform a switching operation of transmitting a data signal transmitted through the data line DL. The switching thin-film transistor may be turned on in response to a scan signal transmitted through the control line SL.

The initialization thin-film transistor may be turned on in response to a sensing scan signal transmitted through the sensing scan line SSL, and transmit an initialization voltage to a gate electrode of the driving thin-film transistor to initialize the gate electrode of the driving thin-film transistor.

The emission control transistor may be turned on in response to an emission control signal transmitted through an emission control line, and as a result, a driving current may flow through the organic light-emitting diode.

The organic light-emitting diode may include a pixel electrode (an anode) and an opposite electrode (a cathode) and may receive a desired voltage from the pixel electrode (the anode) and the opposite electrode (the cathode). The organic light-emitting diode may receive the driving current from the driving thin-film transistor and may emit light to display an image.

Hereinafter, an organic light-emitting display apparatus is described in an embodiment of the display apparatus. However, the display apparatus according to the disclosure is not limited thereto. In another embodiment, a display apparatus according to the disclosure may include an inorganic light-emitting display apparatus, an inorganic electroluminescent (“EL”) display apparatus, or a quantum dot light-emitting display apparatus.

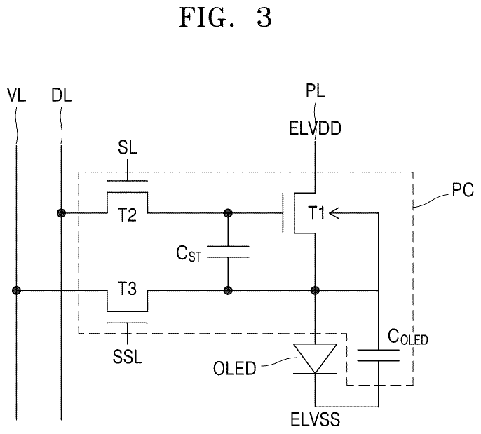

FIG. 3 is a schematic equivalent circuit diagram of the pixel PX of the display apparatus 11 of FIG. 1.

As illustrated in FIG. 3, each pixel PX may include a pixel circuit PC connected to a control line SL and a data line DL and an organic light-emitting diode OLED connected to the pixel circuit PC.

In an embodiment, the pixel circuit PC may include a driving thin-film transistor T1, a switching thin-film transistor T2, a storage capacitor CST, etc., for example.

In an embodiment, the driving thin-film transistor T1 may be connected to a driving voltage line PL and the storage capacitor C_{ST} and may control a driving current flowing from the driving voltage line PL through the organic light-emitting diode OLED, according to a voltage value stored in the storage capacitor C_{ST}, for example. The organic light-emitting diode OLED may emit light having a predetermined brightness, according to the driving current. In an embodiment, a gate electrode of the driving thin-film transistor T1 may be electrically connected to one of electrodes of the storage capacitor C_{ST} and simultaneously, may be electrically connected to a drain electrode of the switching thin-film transistor T2, for example.

In an embodiment, the switching thin-film transistor T2 may be connected to the data line DL and may transmit a data signal Dm input through the data line DL, to the driving thin-film transistor T1, in response to a scan signal input through the control line SL, for example.

An initialization thin-film transistor T3 may include a gate electrode (also referred to as an initialization gate electrode) connected to a sensing scan line SSL, a drain electrode connected to the driving thin-film transistor T1 and the storage capacitor C_{ST}, and a source electrode connected to an initialization voltage line VL. In an embodiment, an initialization voltage may be transmitted to the initialization thin-film transistor T3 through the initialization voltage line VL, for example.

According to cases, the initialization thin-film transistor T3 may be a sensing thin-film transistor. In this case, the initialization voltage line VL may transmit sensing data. In an alternative embodiment, unlike FIG. 3, an additional sensing thin-film transistor may be separately provided in the pixel circuit PC.

In an embodiment, the storage capacitor C_{ST} may be connected to the drain electrode of the switching thin-film transistor T2 and the gate electrode of the driving thin-film transistor T1 and may store a voltage corresponding to the difference between a voltage transmitted from the switching thin-film transistor T2 and an initialization voltage supplied to the initialization thin-film transistor T3, for example. An electrode of the storage capacitor C_{ST} may be electrically connected to the initialization thin-film transistor T3, and a remaining (the other) electrode of the storage capacitor C_{ST} may be electrically connected to the switching thin-film transistor T2 and the driving thin-film transistor T1.

The organic light-emitting diode OLED may receive the driving voltage (hereinafter, also referred to as a first power voltage) ELVDD and the common voltage (hereinafter, also referred to as a second power voltage) ELVSS. In an embodiment, the organic light-emitting diode OLED may receive the second power voltage ELVSS (or the common voltage) through an opposite electrode (a cathode) and receive the first power voltage ELVDD (or the driving voltage) through a pixel electrode (an anode), for example. The organic light-emitting diode OLED may emit light having a predetermined brightness according to a driving current according to a voltage difference between the first power voltage ELVDD (or the driving voltage) and the second power voltage ELVSS (or the common voltage).

A diode capacitor C_{OLED} may be a parasitic capacitor formed in the organic light-emitting diode OLED. When the first initialization voltage (hereinafter also referred to as a voltage of initialization power) Vint is supplied to the anode of the organic light-emitting diode OLED, the diode capacitor C_{OLED} of the parasitic capacitor of the organic light-emitting diode OLED may be discharged, and when the diode capacitor C_{OLED} is discharged, the black representation capacity of the pixel PX may be improved.

It is described with reference to FIG. 3 that the pixel circuit PC includes three thin-film transistors and two storage capacitors. However, the disclosure is not limited thereto. In an embodiment, the pixel circuit PC may include not only two or more storage capacitors, but also four or more thin-film transistors, for example.

In an embodiment, the pixel may include the organic light-emitting diode OLED, the driving thin-film transistor T1, the storage capacitor C_{ST}, and the initialization thin-film transistor T3.

The driving thin-film transistor T1 may be electrically connected to the organic light-emitting diode OLED. A source electrode of the driving thin-film transistor T1 may be electrically connected to the driving voltage line PL, a drain electrode of the driving thin-film transistor T1 may be electrically connected to the organic light-emitting diode OLED, and the gate electrode of the driving thin-film transistor T1 may be electrically connected to the storage capacitor C_{ST} and the drain electrode of the switching thin-film transistor T2.

The storage capacitor C_{ST} may be electrically connected to the gate electrode of the driving thin-film transistor T1 and the organic light-emitting diode OLED. In an embodiment, the storage capacitor C_{ST} may include two electrodes, and an electrode of the storage capacitor C_{ST} may be electrically connected to the drain electrodes of the initialization thin-film transistor T3 and the driving thin-film transistor T1, and a remaining (the other) electrode of the storage capacitor C_{ST} may be electrically connected to the gate electrode of the driving thin-film transistor T1 and the drain electrode of the switching thin-film transistor T2, for example.

A gate electrode (also referred to as a switching gate electrode) of the switching thin-film transistor T2 may be electrically connected to the control line SL, a source electrode of the switching thin-film transistor T2 may be electrically connected to the data line DL, and the drain electrode of the switching thin-film transistor T2 may be electrically connected to a remaining (the other) electrode of the storage capacitor C_{ST} and the gate electrode of the driving thin-film transistor T1.

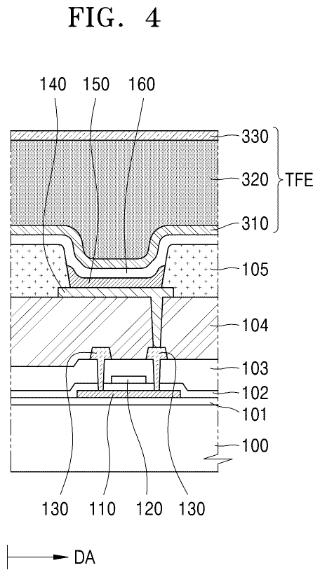

FIG. 4 is a schematic cross-sectional view of a portion of the display apparatus 11 of FIG. 1.

As described above, the substrate 100 may include areas corresponding to the display area DA and the peripheral area PA outside the display area DA. The substrate 100 may include various materials having flexible or bendable properties. In an embodiment, the substrate 100 may include glass, metal, or polymer resins, for example. Also, the substrate 100 may include polymer resins, such as polyethersulphone, polyacrylate, polyetherimide, polyethylene naphthalate, polyethylene terephthalate, polyphenylene sulfide, polyarylate, polyimide, polycarbonate, or cellulose acetate propionate. However, various modifications may be possible. In an embodiment, the substrate 100 may have a multi-layered structure including: two layers each including the polymer resins described above; and a barrier layer between the two layers, the barrier layer including an inorganic material (such as silicon oxide, silicon nitride, silicon oxynitride, or the like), for example.

A buffer layer 101 may be disposed on the substrate 100. The buffer layer 101 may prevent diffusion of impurity ions, prevent the penetration of water or external materials, and perform a function as a barrier layer for planarizing a surface and/or a blocking layer. The buffer layer 101 may include silicon oxide, silicon nitride, or silicon oxynitride. Also, the buffer layer 101 may control a heat provision speed during a crystallization process for forming a semiconductor layer 110, so that the semiconductor layer 110 may be uniformly crystallized.

The semiconductor layer 110 may be disposed on the buffer layer 101. The semiconductor layer 110 may include polysilicon and may include a channel area not doped with impurities and a source area and a drain area at opposite sides of the channel area that are doped with impurities. Here, the impurities may vary according to types of thin-film transistors and may include N-type impurities or P-type impurities. Although not shown in the drawings, the display apparatus according to the disclosure may further include another semiconductor layer disposed in a different layer.

A gate insulating layer 102 may be disposed on the semiconductor layer 110. The gate insulating layer 102 may obtain an insulating property between the semiconductor layer 110 and a gate layer 120. The gate insulating layer 102 may include an inorganic material, such as silicon oxide, silicon nitride, and/or silicon oxynitride, and may be disposed between the semiconductor layer 110 and the gate layer 120. Also, the gate insulating layer 102 may have a shape to correspond to the entirety of the surface of the substrate 100 and may have a structure in which through-holes are formed in predetermined portions. As described above, the insulating layer including an inorganic material may be formed by chemical vapor deposition (“CVD”) or atomic layer deposition (“ALD”). This feature is likewise applied in embodiments described below and their modified embodiments.

The gate layer 120 may be disposed on the gate insulating layer 102. The gate layer 120 may be disposed above the semiconductor layer 110 to overlap the semiconductor layer 110 and may include at least one metal from among Mo, Al, Pt, Pd, Ag, Mg, Au, Ni, Nd, Ir, Cr, Li, Ca, Ti, W, and Cu. Detailed features with respect to the gate layer 120 will be described below. Although not shown, the display apparatus according to the disclosure may further include another gate layer disposed in a different layer.

An inter-insulating layer 103 may be disposed on the gate layer 120. The inter-insulating layer 103 may cover the gate layer 120. The inter-insulating layer 103 may include an inorganic material. In an embodiment, the inter-insulating layer 103 may include metal oxide or metal nitride, for example. In detail, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In some embodiments, the inter-insulating layer 103 may have a dual structure of SiOₓ/SiN_{y} or SiNₓ/SiO_{y}.

A conductive layer 130 may be disposed above the inter-insulating layer 103. The conductive layer 130 may serve as an electrode connected to the source area and the drain area of the semiconductor layer 110 through a through-hole included in the inter-insulating layer 103.

The conductive layer 130 may include one or more metals selected from among Al, Pt, Pd, Ag, Mg, Au, Ni, Nd, Ir, Cr, Li, Ca, Mo, Ti, W, and Cu. In an embodiment, the conductive layer 130 may include a Ti layer, an Al layer, and/or a Cu layer, for example. In an embodiment, the conductive layer 130 may include a Ti/Al/Ti structure, for example.

Although not shown, the display apparatus according to the disclosure may further include another conductive layer disposed in a different layer, and a remaining (the other) conductive layer may be, e.g., a line layer which performs a function of a line. A remaining (the other) conductive layer may include the same material and may have the same layer structure as the conductive layer 130.

An organic insulating layer 104 may be disposed on the conductive layer 130. The organic insulating layer 104 may cover an upper portion of the conductive layer 130 and may have an approximately flat upper surface to serve as a planarization layer. The organic insulating layer 104 may include an organic material, such as acrylic resin, benzocyclobutene (“BCB”), or hexamethyldisiloxane (“HMDSO”), for example. The organic insulating layer 104 may include a single layer or layers and may be modified in various ways.

Although not shown, the display apparatus according to the disclosure may further include another organic insulating layer disposed in a different layer. A remaining (the other) organic insulating layer may be disposed on a remaining (the other) conductive layer described above and may cover an upper portion of a remaining (the other) conductive layer to serve as a planarization layer. A remaining (the other) organic insulating layer may include the same material and may have the same layer structure as the organic insulating layer 104.

A pixel electrode 140 may be disposed on the organic insulating layer 104. In an alternative embodiment, the pixel electrode 140 may be disposed on a remaining (the other) organic insulating layer described above. However, for convenience of explanation, it is assumed that the pixel electrode 140 is disposed on the organic insulating layer 104.

The pixel electrode 140 may be connected to the conductive layer 130 through a contact hole defined in the organic insulating layer 104. A display device may be disposed on the pixel electrode 140. As the display device, an organic light-emitting diode OLED may be used. That is, the organic light-emitting diode OLED may be disposed on the pixel electrode 140, for example. The pixel electrode 140 may include a transmissive conductive layer including transmissive conductive oxide, such as indium tin oxide (“ITO”), indium oxide (“In₂O₃”), or indium zinc oxide (“IZO”), and/or a reflection layer including metal, such as Al or Ag. In an embodiment, the pixel electrode 140 may have a triple-layered structure of ITO/Ag/ITO, for example.

A pixel-defining layer 105 may be disposed above the organic insulating layer 104 and may cover an edge of the pixel electrode 140. That is, the pixel-defining layer 105 may cover the edge of the pixel electrode 140. The pixel-defining layer 105 may define an opening portion corresponding to a pixel, and the opening portion may be formed to expose at least a central portion of the pixel electrode 140. The opening portion may be defined by the pixel-defining layer 105.

The pixel-defining layer 105 may include an organic material, such as polyimide or HMDSO, for example. Also, a spacer may be disposed on the pixel-defining layer 105. For example, although it is not illustrated, the spacer may be disposed in the peripheral area PA, or the spacer may be disposed in the display area DA. The spacer may prevent damage to the organic light-emitting diode OLED, which may be caused by sagging of a mask in a manufacturing process using the mask. The spacer may include an organic insulating material and may include a single layer or layers.

An intermediate layer 150 and an opposite electrode 160 may be disposed in the opening portion. The intermediate layer 150 may include a relatively low molecular-weight material or a relatively high molecular-weight material, and when the intermediate layer 150 includes a relatively low molecular-weight material, the intermediate layer 150 may include a hole injection layer, a hole transport layer, an emission layer, an electron transport layer, and/or an electron injection layer. When the intermediate layer 150 includes a relatively high molecular-weight material, the intermediate layer 150 may generally have a structure including a hole transport layer and an emission layer.

The structure of the intermediate layer 150 is not limited to the structures described above and may vary. In an embodiment, the intermediate layer 150 may include a plurality of organic emission layers to be included in the organic light-emitting diode OLED, for example, and this feature will be described in detail below.

In an embodiment, at least one of the layers included in the intermediate layer 150 may be unitary with the opposite electrode 160, for example. In an embodiment, the intermediate layer 150 may include layers patterned to respectively correspond to a plurality of pixel electrodes 140, for example.

The opposite electrode 160 may include a transmissive conductive layer including a transmissive conductive oxide, such as ITO, In₂O₃, or IZO. The pixel electrode 140 may be used as an anode, and the opposite electrode 160 may be used as a cathode. However, polarities of the electrodes may be the opposite.

The opposite electrode 160 may be disposed in an upper region of the display area DA and may be disposed across the entirety of the surface of the display area DA. That is, the opposite electrode 160 may be unitary to cover a plurality of pixels. A thin-film encapsulation layer TFE may cover an entirety of the display area DA and extend to the peripheral area PA to cover at least a portion of the peripheral area PA.

The thin-film encapsulation layer TFE may include a first inorganic encapsulation layer 310, a second inorganic encapsulation layer 330, and an organic encapsulation layer 320 disposed therebetween. The first and second inorganic encapsulation layers 310 and 330 may include one or more inorganic materials from among Al₂O₃, TiO, Ta₂O₅, HfO₂, ZnO, SiOₓ, SiNₓ, and SiON. The first and second inorganic encapsulation layers 310 and 330 may include a single layer or layers including the materials described above. The first and the second inorganic encapsulation layers 310 and 330 may include the same material as each other or different materials from each other.

Thicknesses of the first and second inorganic encapsulation layers 310 and 330 may be different from each other. The thickness of the first inorganic encapsulation layer 310 may be greater than the thickness of the second inorganic encapsulation layer 330. In an alternative embodiment, the thickness of the second inorganic encapsulation layer 330 may be greater than the thickness of the first inorganic encapsulation layer 310, or the thicknesses of the first and second inorganic encapsulation layer 310 and 330 may be the same as each other.

The organic encapsulation layer 320 may include a monomer-based material or a polymer-based material. The polymer-based material may include acryl-based resins, epoxy-based resins, polyimide, polyethylene, etc. In an embodiment, the organic encapsulation layer 320 may include acrylate, for example.

In another embodiment, the thin-film encapsulation layer TFE may be substituted by a cover member entirely covering the display area DA. The cover member may be disposed to cover not only the display area DA, but also at least a portion of the peripheral area PA. The cover member may include a rigid member (e.g., glass, etc.). According to cases, a transparent filling member may be disposed between the cover member and the opposite electrode 160.

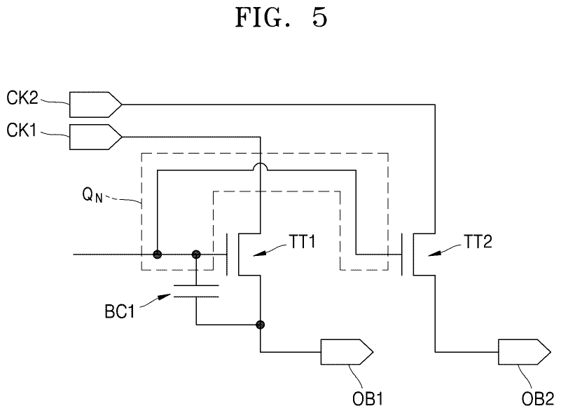

FIG. 5 is a schematic circuit diagram of a portion of the scan driver 20 (refer to FIG. 1) electrically connected to the pixel circuit PC of FIG. 3.

As illustrated in FIG. 5, the scan driver 20 may include a first output terminal OB1, a second output terminal OB2, a first thin-film transistor TT1, a second thin-film transistor TT2, and a first bootstrap capacitor BC1.

The first thin-film transistor TT1 may be electrically connected to the first output terminal OB1. In an embodiment, a gate electrode of the first thin-film transistor TT1 may be electrically connected to a node Q_{N}, for example. A source electrode of the first thin-film transistor TT1 may be electrically connected to a first clock terminal CK1. A drain electrode of the first thin-film transistor TT1 may be electrically connected to the first output terminal OB1. The first clock terminal CK1 may be electrically connected to the controller 40 of FIG. 1 and may receive, from the controller 40, a timing signal desired for the driving of the first thin-film transistor TT1 and transmit the received timing signal to the first thin-film transistor TT1.

The second thin-film transistor TT2 may be electrically connected to the second output terminal OB2. In an embodiment, a gate electrode of the second thin-film transistor TT2 may be electrically connected to the node Q_{N}, for example. A source electrode of the second thin-film transistor TT2 may be electrically connected to a second clock terminal CK2. A drain electrode of the second thin-film transistor TT2 may be electrically connected to the second output terminal OB2. The second clock terminal CK2 may be electrically connected to the controller 40 of FIG. 1 and may receive, from the controller 40, a timing signal desired for the driving of the second thin-film transistor TT2 and transmit the received timing signal to the second thin-film transistor TT2.

The first bootstrap capacitor BC1 may be electrically connected to the gate electrode of the second thin-film transistor TT2 and the second output terminal OB2. In an embodiment, an electrode of the first bootstrap capacitor BC1 may be electrically connected to the node Q_{N}, for example. A remaining (the other) electrode of the first bootstrap capacitor BC1 may be electrically connected to the drain electrode of the first thin-film transistor TT1 and the first output terminal OB1.

The first output terminal OB1 and the second output terminal OB2 may be electrically connected to the pixel circuit PC of FIG. 3. In an embodiment, the first output terminal OB1 may be electrically connected to the gate electrode of the switching thin-film transistor T2 of FIG. 3, for example. The first output terminal OB1 may be electrically connected to the control line SL of FIG. 3. Through the first output terminal OB1, a scan signal may be transmitted to the switching thin-film transistor T2. In an embodiment, the second output terminal OB2 may be electrically connected to the gate electrode of the initialization thin-film transistor T3 of FIG. 3, for example. The second output terminal OB2 may be electrically connected to the sensing scan line SSL of FIG. 3. Through the second output terminal OB2, a sensing scan signal may be transmitted to the initialization thin-film transistor T3.

Referring to FIGS. 3 and 5, the display apparatus in an embodiment may include the organic light-emitting diode OLED, the scan driver 20, and the pixel circuit PC. The pixel circuit PC may include the driving thin-film transistor T1, the switching thin-film transistor T2, and the initialization thin-film transistor T3.

In an embodiment, the scan driver 20 may include the first output terminal OB1 and the second output terminal OB2 and the first thin-film transistor TT1 and the second thin-film transistor TT2 respectively and electrically connected to the first output terminal OB1 and the second output terminal OB2. The scan driver 20 may further include the first bootstrap capacitor BC1 electrically connected to the gate electrode of the second thin-film transistor TT2 and the second output terminal OB2.

In an embodiment, the driving thin-film transistor T1 may be electrically connected to the organic light-emitting diode OLED. The switching thin-film transistor T2 may be electrically connected to the gate electrode of the driving thin-film transistor T1 and may be electrically connected to the first output terminal OB1. The initialization thin-film transistor T3 may be electrically connected to the organic light-emitting diode OLED, may be electrically connected to the source electrode of the driving thin-film transistor T1, and may be electrically connected to the second output terminal OB2.

In an embodiment, the gate electrode of the second thin-film transistor TT2 and the second output terminal OB2 may not be electrically connected to each other. In this specification, that the gate electrode of the second thin-film transistor TT2 and the second output terminal OB2 are not electrically connected to each other may denote that a bootstrap capacitor may be omitted between the gate electrode of the second thin-film transistor TT2 and the second output terminal OB2.

A second bootstrap capacitor for electrically connecting the gate electrode of the first thin-film transistor TT1 and the first output terminal OB1 may be omitted.

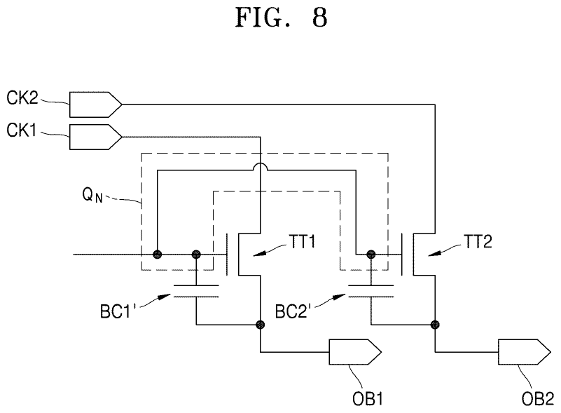

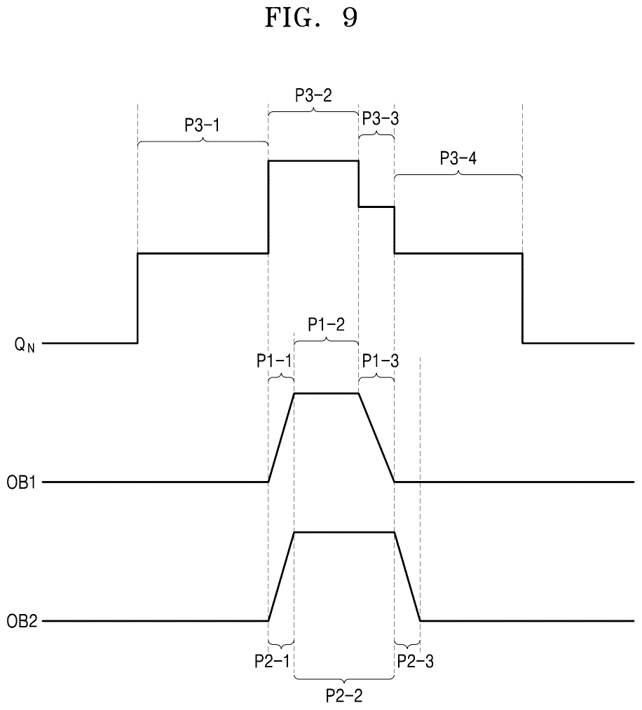

The second bootstrap capacitor (not shown) may be electrically connected to the second thin-film transistor TT2 and may help the second thin-film transistor TT2 stably operate. The second bootstrap capacitor may be a second′ bootstrap capacitor BC2′ (refer to FIG. 8) of FIG. 8 to be described below. The effect of the omission of the second bootstrap capacitor (not shown) may be the same as the effect to be generated by omitting the second′ bootstrap capacitor BC2′ (refer to FIG. 8) to be described below with reference to FIGS. 8 and 9.

In an embodiment, the capacity of the first bootstrap capacitor BC1 may be greater than the capacity of the second bootstrap capacitor (not shown), for example.

In an embodiment, the capacity of the first bootstrap capacitor BC1 may be twice the capacity of the second bootstrap capacitor (not shown), for example. In a display apparatus according to a comparative embodiment, the capacity of a first′ bootstrap capacitor BC1′ (refer to FIG. 8) and the capacity of the second′ bootstrap capacitor BC2′ (refer to FIG. 8) may be the same as each other. The capacity of the first bootstrap capacitor BC1 may be the same as the sum of the capacity of the first′ bootstrap capacitor BC1′ (refer to FIG. 8) and the capacity of the second′ bootstrap capacitor BC2′ (refer to FIG. 8).

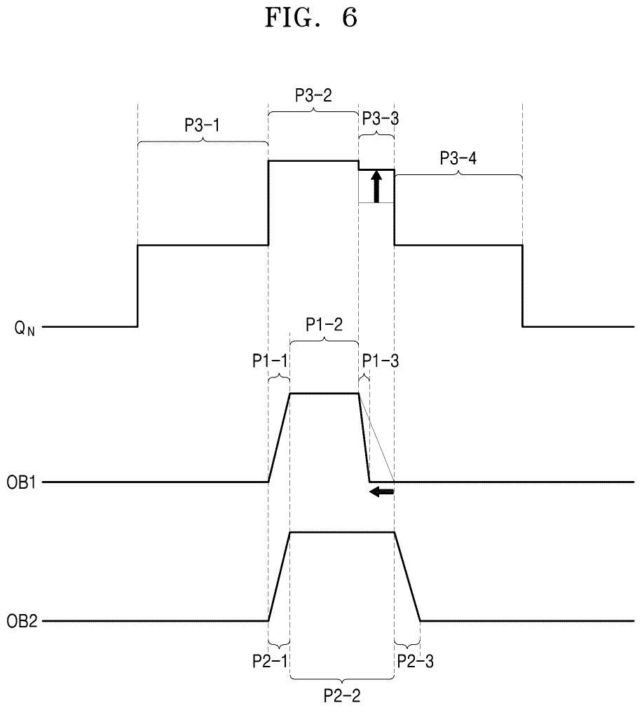

In an embodiment, because the capacity of the first bootstrap capacitor BC1 may be twice the capacity of the second bootstrap capacitor (not shown), the graph of FIG. 6 may be differentiated from the graph of FIG. 8, for example.

In an embodiment, the first output terminal OB1 may output a first signal for turning on or off the switching thin-film transistor T2. The second output terminal OB2 may output a second signal for turning on or off the initialization thin-film transistor T3.

In an embodiment, the first signal may be transmitted to the switching thin-film transistor T2 through the first output terminal OB1 and the control line SL, for example. In an embodiment, the first signal may be a scan signal and the switching thin-film transistor T2 may be turned on according to the scan signal (or a control signal of the switching thin-film transistor T2) transmitted through the control line SL, for example.

In an embodiment, the second signal may be transmitted to the initialization thin-film transistor T3 through the second output terminal OB2 and the sensing scan line SSL, for example. In an embodiment, the second signal may be a sensing scan signal, and the initialization thin-film transistor T3 may be turned on according to the sensing scan signal (or an initialization control signal) transmitted through the sensing scan line SSL, for example.

In an embodiment, the scan driver 20 may further include the node Q_{N} for electrically connecting the gate electrode of the first thin-film transistor TT1 and the gate electrode of the second thin-film transistor TT2. The node Q_{N} may be electrically connected to an electrode of the first bootstrap capacitor BC1. A remaining (the other) electrode of the first bootstrap capacitor BC1 may be electrically connected to the drain electrode of the second thin-film transistor TT2 and the second output terminal OB2.

In an embodiment, the first thin-film transistor TT1 may include a first semiconductor layer having a first area in a plan view. The second thin-film transistor TT2 may include a second semiconductor layer having a second area in a plan view. The first area may be greater than the second area. The second area may be less than the first area.

In an embodiment, the first thin-film transistor TT1 may include the first semiconductor layer including a first active area. The second thin-film transistor TT2 may include the second semiconductor layer including a second active area. A first width of the first active area may be greater than a second width of the second active area. The second width may be less than the first width.

As the size of the first thin-film transistor TT1 is greater than the size of the second thin-film transistor TT2, a fall time (a fall time of a first fall section P1-3 of FIG. 6) of the first signal applied to the first output terminal OB1 may be reduced.

As the size of the second thin-film transistor TT2 is less than the size of the first thin-film transistor TT1, a fall time (a fall time of a second fall section P2-3 of FIG. 6) of the second signal applied to the second output terminal OB2 may be increased. However, because there is no or little coupling effect between the second signal and a third signal applied to the node Q_{N}, an operation of writing a data signal is not affected.

FIG. 6 is a schematic graph of signals respectively applied to the node Q_{N}, the first output terminal OB1, and the second output terminal OB2 of FIG. 5.

As illustrated in FIG. 6, the first signal may be applied to the first output terminal OB1, and the second signal may be applied to the second output terminal OB2. When a signal is sensed through a sensing device, the first signal may be sensed through the first output terminal OB1 and the second signal may be sensed through the second output terminal OB2. The third signal may be applied to the node Q_{N}. When a signal is sensed through a sensing device, the third signal may be sensed through the node Q_{N}.

The first signal may include a first rise section P1-1, a first maintain section P1-2 after the first rise section P1-1, and a first fall section P1-3 after the first maintain section P1-2. The first rise section P1-1, the first maintain section P1-2, and the first fall section P1-3 may sequentially proceed, and the first rise section P1-1, the first maintain section P1-2, and the first fall section P1-3 may form one pulse.

The second signal may include a second rise section P2-1, a second maintain section P2-2 after the second rise section P2-1, and a second fall section P2-3 after the second maintain section P2-2. The second rise section P2-1, the second maintain section P2-2, and the second fall section P2-3 may sequentially proceed, and the second rise section P2-1, the second maintain section P2-2, and the second fall section P2-3 may form one pulse.

In an embodiment, the first rise section P1-1 and the second rise section P2-1 may simultaneously start with each other. A start time of the first rise section P1-1 and a start time of the second rise section P2-1 may be the same or substantially the same as each other.

In an embodiment, the first maintain section P1-2 and the second maintain section P2-2 may simultaneously start with each other. A start time of the first maintain section P1-2 and a start time of the second maintain section P2-2 may be the same or substantially the same as each other.

In an embodiment, the first fall section P1-3 may proceed during the second maintain section P2-2. The first fall section P1-3 may start during the second maintain section P2-2. A start time of the first fall section P1-3 may be earlier than a start time of the second fall section P2-3. An end time of the first fall section P1-3 may be earlier than the start time of the second fall section P2-3. The first fall section P1-3 may end before the second fall section P2-3 starts.

The third signal may include a first high-level section P3-1, a second high-level section P3-2 which is after the first high-level section P3-1 and has a voltage higher than the first high-level section P3-1, and a third high-level section P3-3 which is after the second high-level section P3-2 and has a voltage lower than the second high-level section P3-2. The third signal may further include a fourth high-level section P3-4 which is after the third high-level section P3-3 and has a voltage lower than the third high-level section P3-3.

In an embodiment, the voltage of the first high-level section P3-1 may be lower than the voltage of the second high-level section P3-2. The voltage of the second high-level section P3-2 may be higher than the voltage of the third high-level section P3-3. The voltage of the third high-level section P3-3 may be higher than the voltage of the fourth high-level section P3-4.

In an embodiment, the first high-level section P3-1 may be generated before the first rise section P1-1. The second high-level section P3-2 may simultaneously start with the first rise section P1-1 and the second rise section P2-1. The second high-level section P3-2 may simultaneously end with the first maintain section P1-2. The third high-level section P3-3 may simultaneously start with the first fall section P1-3. The third high-level section P3-3 may simultaneously end as the second fall section P2-3 starts. The fourth high-level section P3-4 may simultaneously start as the second fall section P2-3 starts. The fourth high-level section P3-4 may end after the second fall section P2-3 ends.

In an embodiment, the third high-level section P3-3 may be affected by the first fall section P1-3. The third high-level section P3-3 may be coupled to the first fall section P1-3. In an embodiment, the second high-level section P3-2 may be affected by a voltage drop in the first fall section P1-3, for example. In an embodiment, some portions of the second high-level section P3-2 that have a reduced voltage due to the voltage drop in the first fall section P1-3 may be defined as the third high-level section P3-3, for example.

In an embodiment, the voltage of the third high-level section P3-3 may be higher than the voltage of the first high-level section P3-1. After the first fall section P1-3 ends, the third high-level section P3-3 may be maintained until the second fall section P2-3 starts.

In order to reduce the effect of coupling between the third high-level section P3-3 and the first fall section P1-3, it is desired to reduce the maintaining time of the first fall section P1-3. When the maintaining time of the first fall section P1-3 is reduced, a difference value between the voltage of the third high-level section P3-3 and the voltage of the second high-level section P3-2 may be reduced. Thus, there is the effect of minimizing the brightness change of the pixel due to the effect of coupling between the third high-level section P3-3 and the first fall section P1-3.

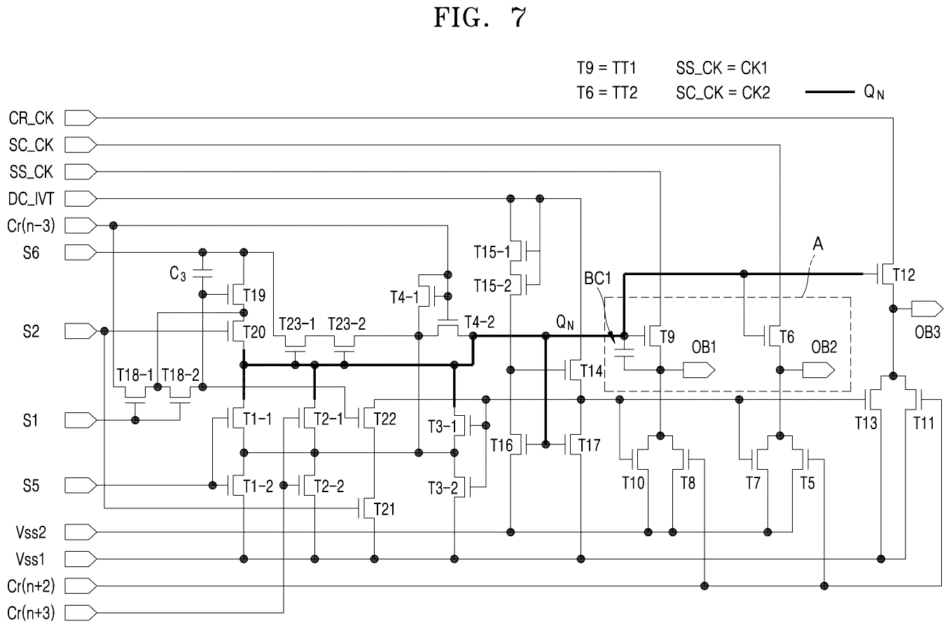

FIG. 7 is a circuit diagram showing an embodiment of the whole circuit diagram including a portion of the scan driver 20 of FIG. 5.

As illustrated in FIG. 7, the scan driver 20 may include a portion A of the scan driver 20 of FIG. 5. A ninth transistor T9 in FIG. 7 may be the first thin-film transistor TT1 of FIG. 5, and a sixth transistor T6 in FIG. 7 may be the second thin-film transistor TT2 of FIG. 5.

The scan driver 20 of FIG. 7 may be a circuit which controls a gate driving operation of pixels in two rows or two columns. In order to control the gate driving operation of the pixels in the two rows or the two columns, a first transistor may be realized as a first-1 transistor T1-1 and a first-2 transistor T1-2, a second transistor may be realized as a second-1 transistor T2-1 and a second-2 transistor T2-2, a third transistor may be realized as a third-1 transistor T3-1 and a third-2 transistor T3-2, and a fourth transistor may be realized as a fourth-1 transistor T4-1 and a fourth-2 transistor T4-2. Here, the first-1 transistor T1-1, the second-1 transistor T2-1, the third-1 transistor T3-1, and the fourth-1 transistor T4-1 may be elements which control the gate driving operation of the pixels in one row or one column, and the first-2 transistor T1-2, the second-2 transistor T2-2, the third-2 transistor T3-2, and the fourth-2 transistor T4-2 may be elements which control the gate driving operation of the pixels in a remaining (the other) row or a remaining (the other) column. Thus, according to cases, each of the first to fourth transistors may be realized as only one transistor.

The first-1 transistor T1-1 and the first-2 transistor T1-2 may be electrically connected to the node Q_{N}. A gate electrode of each of the first-1 transistor T1-1 and the first-2 transistor T1-2 may be connected to a third control terminal S5. In an embodiment, a source electrode of the first-1 transistor T1-1 and may be electrically connected to the node Q_{N} and a drain electrode of the first-1 transistor T1-1 may be electrically connected to a source electrode of the first-2 transistor T1-2, for example. The drain electrode of the first-1 transistor T1-1 and the source electrode of the first-2 transistor T1-2 may be electrically connected to each other. The source electrode of the first-1 transistor T1-1 and a drain electrode of the first-2 transistor T1-2 may be electrically connected to the second-1 transistor T2-1, the second-2 transistor T2-2, the third-1 transistor T3-1, the third-2 transistor T3-2, the fourth-1 transistor T4-1, and the fourth-2 transistor T4-2. In an embodiment, the source electrode of the first-2 transistor T1-2 may be electrically connected to a first power terminal V_{SS}1, for example.

The second-1 transistor T2-1 and the second-2 transistor T2-2 may be electrically connected to the node Q_{N}. A gate electrode of each of the second-1 transistor T2-1 and the second-2 transistor T2-2 may be electrically connected to an n+3^{th} carry signal terminal Cr(n+3). In an embodiment, an electrode of the second-1 transistor T2-1 may be electrically connected to the node Q_{N}, for example. A remaining (the other) electrode of the second-1 transistor T2-1 and an electrode of the second-2 transistor T2-2 may be electrically connected to each other. A remaining (the other) electrode of the second-1 transistor T2-1 and the electrode of the second-2 transistor T2-2 may be electrically connected to the first-1 transistor T1-1, the first-2 transistor T1-2, the third-1 transistor T3-1, the third-2 transistor T3-2, the fourth-1 transistor T4-1, and the fourth-2 transistor T4-2. In an embodiment, a remaining (the other) electrode of the second-2 transistor T2-2 may be electrically connected to a first power terminal V_{SS}1, for example. The n+3^{th} carry signal terminal Cr(n+3) may receive a carry signal of an n+3^{th} stage from the controller 40 of FIG. 1.

The third-1 transistor T3-1 and the third-2 transistor T3-2 may be electrically connected to the node Q_{N}. A gate electrode of each of the third-1 transistor T3-1 and the third-2 transistor T3-2 may be electrically connected to a twenty-second transistor T22, a seventeenth transistor T17, and a fourteenth transistor T14 and may be electrically connected to a gate electrode of each of a tenth transistor T10, a seventh transistor T7, and a thirteenth transistor T13. In an embodiment, an electrode of the third-1 transistor T3-1 may be electrically connected to the node Q_{N}, for example. A remaining (the other) electrode of the third-1 transistor T3-1 and an electrode of the third-2 transistor T3-2 may be electrically connected to each other. A remaining (the other) electrode of the third-1 transistor T3-1 and the electrode of the third-2 transistor T3-2 may be electrically connected to the first-1 transistor T1-1, the first-2 transistor T1-2, the second-1 transistor T2-1, the second-2 transistor T2-2, the fourth-1 transistor T4-1, and the fourth-2 transistor T4-2. In an embodiment, a remaining (the other) electrode of the third-2 transistor T3-2 may be electrically connected to the first power terminal V_{SS}1, for example.

An electrode and a gate electrode of the fourth-1 transistor T4-1 and a gate electrode of the fourth-2 transistor T4-2 may be electrically connected to an n−3^{th} carry signal terminal Cr(n−3). A remaining (the other) electrode of the fourth-1 transistor T4-1 may be electrically connected to the electrode of the fourth-2 transistor T4-2 and may be electrically connected to a twenty-third-1 transistor T23-1 and a twenty-third-2 transistor T23-2. A remaining (the other) electrode of the fourth-2 transistor T4-2 may be electrically connected to the node Q_{N}.

A fifth transistor T5 may be electrically connected to the sixth transistor T6, the seventh transistor T7, and the second output terminal OB2 and may be electrically connected to a second power terminal V_{SS}2. In an embodiment, an electrode of the fifth transistor T5 may be electrically connected to the seventh transistor T7, the sixth transistor T6, and the second output terminal OB2, for example. A gate electrode of the fifth transistor T5 may be electrically connected to an n+2^{th} carry signal terminal Cr(n+2) and an eleventh transistor T11. A remaining (the other) electrode of the fifth transistor T5 may be electrically connected to a sixteenth transistor T16, the tenth transistor T10, an eighth transistor T8, and the seventh transistor T7 and may be electrically connected to the second power terminal V_{SS}2. The n+2^{th} carry signal terminal Cr(n+2) may receive a carry signal of an n+2^{th} stage from the controller 40 of FIG. 1.

The sixth transistor T6 may be the second thin-film transistor TT2 of FIG. 5. An electrode of the sixth transistor T6 may be electrically connected to a second clock terminal SC_CK which transmits a scan control signal. The second clock terminal SC_CK may be understood as the second clock terminal CK2 of FIG. 5 or a line connected to the second clock terminal CK2 of FIG. 5. A gate electrode of the sixth transistor T6 may be electrically connected to the node Q_{N}. A drain electrode of the sixth transistor T6 may be electrically connected to the second output terminal OB2 and may be electrically connected to the fifth transistor T5 and the seventh transistor T7. The second clock terminal SC_CK may receive a clock signal from the controller 40 of FIG. 1 and may transmit the received clock signal to the sixth transistor T6.

A gate electrode of the seventh transistor T7 may be electrically connected to the third-1 transistor T3-1, the third-2 transistor T3-2, the twenty-second transistor T22, the seventeenth transistor T17, the fourteenth transistor T14, the tenth transistor T10, and the thirteenth transistor T13. A source electrode of the seventh transistor T7 may be electrically connected to the sixth transistor T6 and the second output terminal OB2. A drain electrode of the seventh transistor T7 may be electrically connected to the second power terminal V_{SS}2.

A gate electrode of the eighth transistor T8 may be electrically connected to the n+2^{th} carry signal terminal Cr(n+2). A source electrode of the eighth transistor T8 may be electrically connected to the ninth transistor T9 and the first output terminal OB1, may be electrically connected to the first bootstrap capacitor BC1, and may be electrically connected to the tenth transistor T10. A drain electrode of the eighth transistor T8 may be electrically connected to the second power terminal V_{SS}2.

The ninth transistor T9 may be the first thin-film transistor TT1 of FIG. 5. A gate electrode of the ninth transistor T9 may be electrically connected to the node Q_{N} and may be electrically connected to the first bootstrap capacitor BC1. A source electrode of the ninth transistor T9 may be electrically connected to the first clock terminal SS_CK. The first clock terminal SS_CK may correspond to the first clock terminal CK1 of FIG. 5. A drain electrode of the ninth transistor T9 may be electrically connected to the first output terminal OB1 and the first bootstrap capacitor BC1 and may be electrically connected to the eighth transistor T8 and the tenth transistor T10. In an embodiment, an electrode of the first bootstrap capacitor BC1 may be electrically connected to the first output terminal OB1 and the drain electrode of the ninth transistor T9, and a remaining (the other) electrode of the first bootstrap capacitor BC1 may be electrically connected to the node Q_{N} and the gate electrode of the ninth transistor T9, for example. The first clock terminal SS_CK may receive a clock signal from the controller 40 of FIG. 1 and transmit the received clock signal to the ninth transistor T9.

A gate electrode of the tenth transistor T10 may be electrically connected to the twenty-second transistor T22, the third-1 transistor T3-1, the third-2 transistor T3-2, the seventeenth transistor T17, the seventh transistor T7, and the thirteenth transistor T13. A source electrode of the tenth transistor T10 may be electrically connected to the ninth transistor T9, the first output terminal OB1, and the eighth transistor T8. A drain electrode of the tenth transistor T10 may be electrically connected to a second power terminal V_{SS}2.

A source electrode of the eleventh transistor T11 may be electrically connected to a third output terminal OB3, a twelfth transistor T12, and the thirteenth transistor T13. A gate electrode of the eleventh transistor T11 may be electrically connected to the n+2^{th} carry signal terminal Cr(n+2). A drain electrode of the eleventh transistor T11 may be electrically connected to the first power terminal V_{SS}1.

The twelfth transistor T12 may be electrically connected to a third clock terminal CR_CK, the third output terminal OB3, and the node Q_{N}. A source electrode of the twelfth transistor T12 may be electrically connected to the third clock terminal CR_CK, a gate electrode of the twelfth transistor T12 may be electrically connected to the node Q_{N}, and a drain electrode of the twelfth transistor T12 may be electrically connected to the third output terminal OB3, the eleventh transistor T11, and the thirteenth transistor T13.

The third clock terminal CR_CK may be electrically connected to the controller 40 of FIG. 1 and may receive a carry clock signal from the controller 40 and transmit the carry clock signal to the twelfth transistor T12.

A source electrode of the thirteenth transistor T13 may be electrically connected to the twelfth transistor T12, the third output terminal OB3, and the eleventh transistor T11. A gate electrode of the thirteenth transistor T13 may be electrically connected to the twenty-second transistor T22, the third-1 transistor T3-1, the third-2 transistor T3-2, the sixteenth transistor T16, the seventeenth transistor T17, the tenth transistor T10, the seventh transistor T7, and the fifth transistor T5. A drain electrode of the thirteenth transistor T13 may be electrically connected to the first power terminal V_{SS}1.

A source electrode of the fourteenth transistor T14 may be electrically connected to a direct current power terminal DC_IVT, a fifteenth-1 transistor T15-1, and a fifteenth-2 transistor T15-2. A gate electrode of the fourteenth transistor T14 may be electrically connected to the fifteenth-2 transistor T15-2 and the sixteenth transistor T16. A drain electrode of the fourteenth transistor T14 may be electrically connected to the twenty-second transistor T22, the third-1 transistor T3-1, the third-2 transistor T3-2, the seventeenth transistor T17, the tenth transistor T10, the seventh transistor T7, and the thirteenth transistor T13.

A fifteenth transistor may be realized as the fifteenth-1 transistor T15-1 and the fifteenth-2 transistor T15-2. A source electrode of the fifteenth-1 transistor T15-1 may be electrically connected to a direct current power line and may be electrically connected to a gate electrode of the fifteenth-1 transistor T15-1 and a gate electrode of the fifteenth-2 transistor T15-2. A drain electrode of the fifteenth-1 transistor T15-1 may be electrically connected to a source electrode of the fifteenth-2 transistor T15-2, and a drain electrode of the fifteenth-2 transistor T15-2 may be electrically connected to the fourteenth transistor T14 and the sixteenth transistor T16.

A source electrode of the sixteenth transistor T16 may be electrically connected to the fifteenth-2 transistor T15-2 and the fourteenth transistor T14. A gate electrode of the sixteenth transistor T16 may be electrically connected to the node Q_{N} and the seventeenth transistor T17. A source electrode of the sixteenth transistor T16 may be electrically connected to the second power terminal VSS2.

A source electrode of the seventeenth transistor T17 may be electrically connected to the fourteenth transistor T14, the twenty-second transistor T22, the third-1 transistor T3-1, the third-2 transistor T3-2, the tenth transistor T10, the seventh transistor T7, and the thirteenth transistor T13. A gate electrode of the seventeenth transistor T17 may be electrically connected to the node Q_{N} and the sixteenth transistor T16 and a drain electrode of the seventeenth transistor T17 may be electrically connected to the first power terminal V_{SS}1.

An eighteenth transistor may be realized as an eighteenth-1 transistor T18-1 and an eighteenth-2 transistor T18-2. A source electrode of the eighteenth-1 transistor T18-1 may be electrically connected to the n−3^{th} carry signal terminal Cr(n−3) and may be electrically connected to the fourth-1 transistor T4-1. A gate electrode of the eighteenth-1 transistor T18-1 and a gate electrode of the eighteenth-2 transistor T18-2 may be electrically connected to the first control terminal S1. A drain electrode of the eighteenth-1 transistor T18-1 may be electrically connected to a source electrode of the eighteenth-2 transistor T18-2 and may be electrically connected to a nineteenth transistor T19 and a twentieth transistor T20. A drain electrode of the eighteenth-2 transistor T18-2 may be electrically connected to the nineteenth transistor T19 and an additional capacitor C3 and may be electrically connected to the twenty-second transistor T22. The n−3^{th} carry signal terminal Cr(n−3) may receive a carry signal of an n−3^{th} stage from the controller 40 of FIG. 1.

A source electrode of the nineteenth transistor T19 may be electrically connected to a fourth control line S6 and an electrode of the additional capacitor C3 and a gate electrode of the nineteenth transistor T19 may be electrically connected to a remaining (the other) electrode of the additional capacitor C3 and the eighteenth-2 transistor T18-2. A drain electrode of the nineteenth transistor T19 may be electrically connected to the eighteenth-1 transistor T18-1 and the eighteenth-2 transistor T18-2 and may be electrically connected to the twentieth transistor T20.

A source electrode of the twentieth transistor T20 may be electrically connected to the nineteenth transistor T19, the eighteenth-1 transistor T18-1, and the eighteenth-2 transistor T18-2. A gate electrode of the twentieth transistor T20 may be electrically connected to a second control terminal S2 and a twenty-first transistor T21. A drain electrode of the twentieth transistor T20 may be electrically connected to the node Q_{N}.

A source electrode of the twenty-first transistor T21 may be electrically connected to the twenty-second transistor T22, a gate electrode of the twenty-first transistor T21 may be electrically connected to the second control terminal S2 and the twentieth transistor T20, and a drain electrode of the twenty-first transistor T21 may be electrically connected to the first power terminal V_{SS}1.

A source electrode of the twenty-second transistor T22 may be electrically connected to the third-2 transistor T3-2, the fourteenth transistor T14, the seventeenth transistor T17, the tenth transistor T10, the seventh transistor T7, and the thirteenth transistor T13. A gate electrode of the twenty-second transistor T22 may be electrically connected to the eighteenth-2 transistor T18-2, the nineteenth transistor T19, and the additional capacitor C3. A drain electrode of the twenty-second transistor T22 may be electrically connected to the twenty-first transistor T21.

A twenty-third transistor may be realized as a twenty-third-1 transistor T23-1 and a twenty-third-2 transistor T23-2. A source electrode of the twenty-third-1 transistor T23-1 may be electrically connected to the fourth control line S6, the additional capacitor C3, and the nineteenth transistor T19. A gate electrode of the twenty-third-1 transistor T23-1 may be electrically connected to the node Q_{N}. A drain electrode of the twenty-third-1 transistor T23-1 may be electrically connected to a source electrode of the twenty-third-2 transistor T23-2. A gate electrode of the twenty-third-2 transistor T23-2 may be electrically connected to the node Q_{N}. A drain electrode of the twenty-third-2 transistor T23-2 may be electrically connected to the fourth-1 transistor T4-1, the fourth-2 transistor T4-2, the first-1 transistor T1-1, the first-2 transistor T1-2, the second-1 transistor T2-1, the second-2 transistor T2-2, the third-1 transistor T3-1, and the third-2 transistor T3-2.

FIG. 8 is a schematic circuit diagram of a portion of the scan driver 20 electrically connected to a pixel circuit of a display apparatus according to a comparative embodiment.

For reference, in the circuit diagram of FIG. 8, the same features as the circuit diagram of FIG. 5 or features repeated in the circuit diagram of FIG. 5 may be omitted, and different features from the circuit diagram of FIG. 5 may be mainly described.

As illustrated in FIG. 8, a portion of the scan driver 20 may include a first′ bootstrap capacitor BC1′ and a second′ bootstrap capacitor BC2′.

Unlike FIG. 5, the circuit diagram of FIG. 8 may further include the second′ bootstrap capacitor BC2′. In an embodiment, the capacity of the first′ bootstrap capacitor BC1′ and the capacity of the second′ bootstrap capacitor BC2′ may be the same as each other, for example.

The capacity of the first bootstrap capacitor BC1 of FIG. 5 may be the same as the sum of the capacity of the first′ bootstrap capacitor BC1′ and the capacity of the second bootstrap capacitor BC2′ of FIG. 8. In an embodiment, in FIG. 8, the second′ bootstrap capacitor BC2′ may be omitted, and the first′ bootstrap capacitor BC1′ may have the capacity increased by a value corresponding to the capacity of the omitted second′ bootstrap capacitor BC2′, for example. The embodiment of FIG. 8, in which the second′ bootstrap capacitor BC2′ is omitted and the capacity of the first bootstrap capacitor BC1′ is increased, may correspond to FIG. 5.

FIG. 9 is a schematic graph of signals respectively applied to a node, a first′ output terminal OB1, and a second′ output terminal OB2 of FIG. 8.

The difference between the graph of FIG. 9 and the graph of FIG. 6 may be a voltage value of the third high-level section P3-3 and a fall time of the first fall section P1-3. As described above with reference to FIG. 6, when the fall time of the first fall section P1-3 is reduced, a voltage drop phenomenon of the third high-level section P3-3 which is coupled to the first fall section P1-3 may be reduced.

Like this, in order to reduce the fall time of the first fall section P1-3, the capacity of the first′ bootstrap capacitor BC1′ connected to the first output terminal OB1 may be increased. As the fall time of the first fall section P1-3 is reduced, a voltage difference between the voltage applied to the node Q_{N} in the second high-level section P3-2 and the voltage applied to the node Q_{N} in the third high-level section P3-3 may be reduced or minimized and the drop of the voltage applied to the node Q_{N} may be prevented or minimized. As the drop of the voltage applied to the node Q_{N} is prevented or minimized, the output change of the second output terminal OB2 may not be affected or may be little affected, even when the second′ bootstrap capacitor BC2′ is omitted. Ultimately, the change in voltage applied to the node Q_{N} may be less in the case where the scan driver 20 having the circuit diagram of FIG. 5 is used than in the case where the scan driver 20 having the circuit diagram of FIG. 8 is used. Also, as the change in voltage applied to the node Q_{N} is reduced, the change in gate voltage of the first thin-film transistor TT1 and the second thin-film transistor TT2 may be minimized, and thus, data may be stably written in the storage capacitor. As the data is stably written in the storage capacitor, the image quality of the display apparatus in an embodiment may be improved compared to the image quality of the display apparatus according to the comparative embodiment.

Also, as the second′ bootstrap capacitor BC2′ is omitted, the area of the scan driver 20 may be reduced according to the omitted space of the second′ bootstrap capacitor BC2′. Ultimately, an area of the peripheral area PA or a bezel area may be more reduced in the case where the scan driver 20 having the circuit diagram of FIG. 5 is used than in the case where the scan driver 20 having the circuit diagram of FIG. 8 is used. A bezel of the display apparatus in an embodiment may be slimmer than a bezel of the display apparatus according to the comparative embodiment.

According to the one or more of the described embodiments, a display apparatus capable of minimizing interference between signals may be realized. However, the effects described above do not limit the scope of the disclosure.

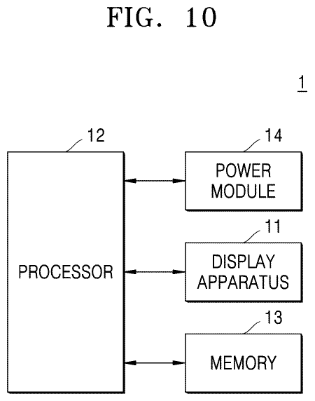

FIG. 10 is a block diagram of an electronic device.

Referring to FIG. 10, the electronic device 1 may comprise the display apparatus 11, a processor 12, a memory 13, and a power module 14.

The processor 12 may comprise at least one of a central processing unit (CPU), an application processor (AP), a graphic processing unit (GPU), a communication processor (CP), an image signal processor (ISP), and a controller.

Data for operations of the processor 12 or the display apparatus 11 may be stored in the memory 13. When the processor 12 executes an application stored in the memory 13, image data signals and/or input control signals may be transferred to the display apparatus 11, and the display apparatus 11 may process the received signals to output image information through a display screen.

The power module 14 may comprise a power supply module such as a power adapter or a battery device, and a power conversion module that converts power supplied by the power supply module to generate power necessary for operation of the electronic device 1.

At least one of the components of the display apparatus 11 described above may be comprised in the electronic device 1 to the embodiments described above. Additionally, some individual modules functionally comprised in one module may be comprised in the display apparatus while others may be provided separately from the display apparatus.

The display apparatus 11 of FIG. 10 may comprise one of the examples of the display panel 10 described in FIGS. 1 to 9. For convenience of description, other descriptions are omitted, but one of ordinary skill in the art can easily and clearly understand the display apparatus 11 of FIG. 10 based on the descriptions of FIGS. 1 to 9.

In an embodiment, the electronic device 1 may comprise the memory 13 which stores data information, the processor 12 which generates data signals and/or control signals based on the data information, and the display apparatus 11 that operates based on the data signals and/or control signals.

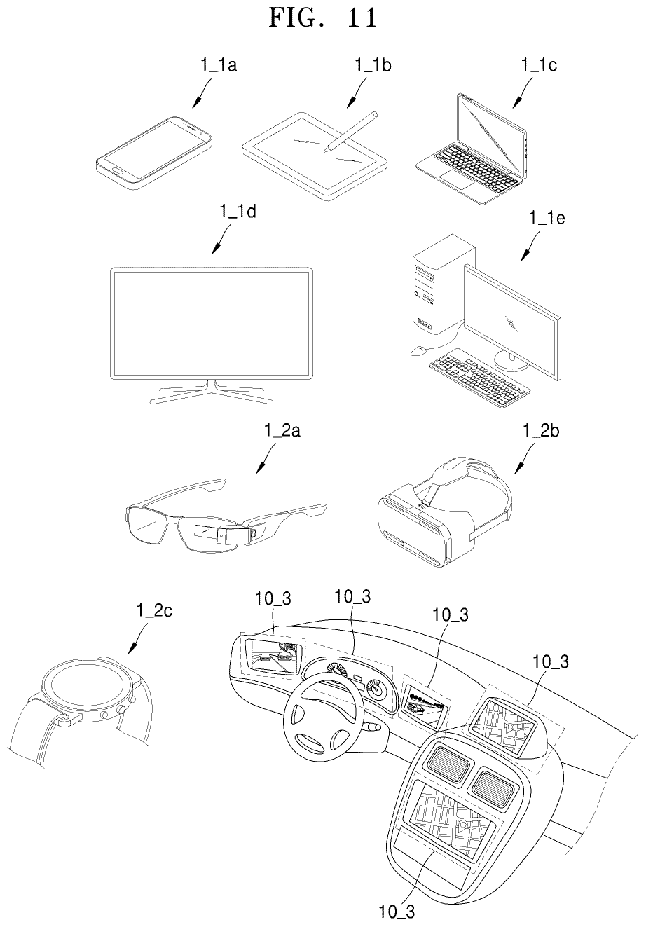

FIG. 11 shows schematic views of various electronic devices.

Referring to FIG. 11, the electronic device 1 may comprise not only electronic devices for displaying image such as smartphone 1_1a, tablet PC 1_1b, laptop 1_1c, TV 1_1d, and desktop monitor 1_1e, but also wearable electronic devices comprising display modules such as smart glass 1_2a, head-mounted display 1_2b, and smart watch 1_2c, as well as vehicle electronic device 10_3 comprising display module such as instrument panel, center fascia, dashboard equipped with Center Information Display, and rearview mirror display of automobile.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by one of ordinary skill in the art that various changes in form and details may be made therein without departing from the spirit and scope as defined by the following claims.

What is claimed is:

1. A display apparatus comprising:
an organic light-emitting diode;
a scan driver comprising:
a first output terminal;
a second output terminal;
a first thin-film transistor electrically connected to the first output terminal;
a second thin-film transistor electrically connected to the second output terminal and comprising:
a gate electrode; and
a bootstrap capacitor electrically connected to the gate electrode of the first thin-film transistor and the first output terminal;
a driving thin-film transistor electrically connected to the organic light-emitting diode and comprising:
a gate electrode; and
a source electrode;
a switching thin-film transistor electrically connected to the gate electrode of the driving thin-film transistor and comprising:
a switching gate electrode electrically connected to the first output terminal; and
an initialization thin-film transistor electrically connected to the organic light-emitting diode and the source electrode of the driving thin-film transistor and comprising:
an initialization gate electrode electrically connected to the second output terminal,
wherein the gate electrode of the second thin-film transistor and the second output terminal are not electrically connected to each other.

2. The display apparatus of claim 1, wherein the first output terminal outputs a first signal for turning on or off the switching thin-film transistor, and
the second output terminal outputs a second signal for turning on or off the initialization thin-film transistor.

3. The display apparatus of claim 1, wherein the scan driver further comprises a node electrically connecting a gate electrode of the first thin-film transistor to a gate electrode of the second thin-film transistor.

4. The display apparatus of claim 3, wherein the node is electrically connected to an electrode of the bootstrap capacitor.

5. The display apparatus of claim 4, wherein another electrode of the bootstrap capacitor is electrically connected to a drain electrode of the second thin-film transistor and the second output terminal.

6. The display apparatus of claim 2, wherein the first signal comprises a first rise section, a first maintain section after the first rise section, and a first fall section after the first maintain section, and
the second signal comprises a second rise section, a second maintain section after the second rise section, and a second fall section after the second maintain section.

7. The display apparatus of claim 6, wherein the first rise section and the second rise section start simultaneously with each other.

8. The display apparatus of claim 6, wherein the first fall section starts during the second maintain section.

9. The display apparatus of claim 8, wherein the first fall section ends before the second fall section starts.

10. The display apparatus of claim 6, wherein the scan driver further comprises a node electrically connecting a gate electrode of the first thin-film transistor to a gate electrode of the second thin-film transistor which corresponds to the gate electrode of the second thin-film transistor,
a third signal is applied to the node, and
the third signal comprises a first high-level section, a second high-level section, and a third high-level section, wherein the second high-level section starts, after the first high-level section, simultaneously with the first rise section and has a voltage higher than the first high-level section, and the third high-level section starts, after the second high-level section, simultaneously with the first fall section and has a voltage lower than the second high-level section.

11. The display apparatus of claim 10, wherein the third high-level section has a voltage higher than the first high-level section.

12. The display apparatus of claim 11, wherein the third high-level section is maintained, after the first fall section ends, until the second fall section starts.

13. The display apparatus of claim 12, wherein the third signal further comprises a fourth high-level section which starts, after the third high-level section, simultaneously with the second fall section and has a voltage lower than the third high-level section.

14. The display apparatus of claim 13, wherein the fourth high-level section ends after the second fall section ends.

15. The display apparatus of claim 1, wherein the first thin-film transistor comprises a first semiconductor layer having a first area in a plan view, the second thin-film transistor comprises a second semiconductor layer having a second area in the plan view, and
the first area is less than the second area.

16. The display apparatus of claim 1, wherein the first thin-film transistor comprises a first semiconductor layer comprising a first active area, the second thin-film transistor comprises a second semiconductor layer comprising a second active area, and
a first width of the first active area is less than a second width of the second active area.

17. A display apparatus comprising:
an organic light-emitting diode;
a scan driver comprising:
a first output terminal;
a second output terminal;
a first thin-film transistor electrically connected to the first output terminal and comprising:
a gate electrode;
a second thin-film transistor electrically connected to the second output terminal and comprising:
a gate electrode; and
a first bootstrap capacitor electrically connected to the gate electrode of the first thin-film transistor and the first output terminal, the scan driver non-including a second bootstrap capacitor electrically connected between the gate electrode of the second thin-film transistor and the second output terminal;
a driving thin-film transistor electrically connected to the organic light-emitting diode and comprising:
a source electrode;
a switching thin-film transistor electrically connected to a gate electrode of the driving thin-film transistor and comprising:
a switching gate electrode electrically connected to the first output terminal; and
an initialization thin-film transistor electrically connected to the organic light-emitting diode and the source electrode of the driving thin-film transistor and comprising:
an initialization gate electrode electrically connected to the second output terminal.

18. The display apparatus of claim 17, wherein a capacity of the first bootstrap capacitor is greater than a capacity of the second bootstrap capacitor, and wherein the capacity of the first bootstrap capacitor is twice the capacity of the second bootstrap capacitor.

19. The display apparatus of claim 17, wherein the first thin-film transistor comprises a first semiconductor layer having a first area in a plan view, the second thin-film transistor comprises a second semiconductor layer having a second area in the plan view, and
the second area is less than the first area.

20. An electronic apparatus comprising:
a memory which stores data information;
a processor which generates data signals and/or control signals based on the data information; and
a display apparatus which operates based on the data signals and/or the control signals, wherein the display apparatus comprising:
an organic light-emitting diode;
a scan driver comprising:
a first output terminal;
a second output terminal;
a first thin-film transistor electrically connected to the first output terminal;
a second thin-film transistor electrically connected to the second output terminal and comprising:
a gate electrode; and
a bootstrap capacitor electrically connected to a the gate electrode of the first thin-film transistor and the first output terminal;
a driving thin-film transistor electrically connected to the organic light-emitting diode and comprising:
a gate electrode; and
a source electrode;
a switching thin-film transistor electrically connected to a the gate electrode of the driving thin-film transistor and comprising:
a switching gate electrode electrically connected to the first output terminal; and
an initialization thin-film transistor electrically connected to the organic light-emitting diode and a the source electrode of the driving thin-film transistor and comprising:
an initialization gate electrode electrically connected to the second output terminal,
wherein the gate electrode of the second thin-film transistor and the second output terminal are not electrically connected to each other.
